(19) United States
(12) Patent Application Publication
(10) Pub. No.: US 2025/0359024 A1
(43) Pub. Date: Nov. 20, 2025

(54) HIGH PERFORMANCE EMBEDDED 1T1C MEMORY CELLS

(71) Applicant: Taiwan Semiconductor Manufacturing Company, Ltd., Hsinchu (TW)

(72) Inventors: Chieh Lee, Hsinchu (TW); Chi Lo, Hsinchu (TW); Yi-Ching LIU, Hsinchu (TW); Yih Wang, Hsinchu (TW)

(73) Assignee: Taiwan Semiconductor Manufacturing Company, Ltd., Hsinchu (TW)

(21) Appl. No.: 19/285,471

(22) Filed: Jul. 30, 2025

Related U.S. Application Data
(63) Continuation of application No. 18/642,282, filed on Apr. 22, 2024.
(60) Provisional application No. 63/615,585, filed on Dec. 28, 2023.

(51) Int. Cl. H10B 12/00; H01L 25/07; H10D 62/17; H10D 62/80

(52) U.S. Cl. CPC H10B 12/33; H01L 25/072; H10B 12/033; H10B 12/482; H10B 12/488; H10D 62/221; H10D 62/871

(57) ABSTRACT

A semiconductor memory device includes a plurality of transistors disposed along a major surface of a substrate, a plurality of metallization layers including a plurality of metal tracks and disposed over the major surface of the substrate, and a plurality of memory cells formed within one or more of the metallization layers. At least one of the plurality of transistors is electrically coupled to the plurality of memory cells. Each of the plurality of memory cells includes an access transistor and a storage capacitor electrically coupled to each other in series and physically arranged with respect to each other along a vertical direction.

### CROSS-REFERENCE TO RELATED APPLICATION

This application is a continuation of U.S. patent application Ser. No. 18/642,282, filed Apr. 22, 2024, which claims the benefit of U.S. Provisional Application No. 63/615,585, filed Dec. 28, 2023, all of which are incorporated herein by reference in their entireties for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view illustrating a semiconductor memory device in accordance with some embodiments.

FIG. 2 is a schematic cross-sectional view illustrating the semiconductor memory device taken along line A-A of FIG. 1.

FIG. 3 is a top view illustrating the semiconductor memory device of FIG. 1 in accordance with some embodiments.

FIG. 4 is a flow diagram illustrating a method for manufacturing a semiconductor memory device in accordance with some embodiments.

FIGS. 5 to 11 are schematic cross-sectional views illustrating intermediate stages of the method as depicted in FIG. 4 in accordance with some embodiments.

FIG. 12 is another flow diagram illustrating a method for manufacturing a semiconductor memory device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The disclosure relates to a semiconductor memory device and a method for manufacturing the same. In accordance with some embodiments of the present disclosure, the semiconductor memory device includes a plurality of transistors disposed along a major surface (or a front surface) of a substrate and thus formed in a front-end-of-line (FEOL) network, a plurality of metallization layers (such as M0, M1, M2, M3, M4, M5, M6, M7, M8, etc.) including a plurality of metal tracks and metal vias and disposed over the major surface of the substrate, and at least an array of memory cells formed within one or more of the metallization layers (such as M5, M6, and M7) and thus formed in a back-end-of-line (BEOL) network. At least one of the plurality of transistors formed in the FEOL network, working as a peripheral circuit, such as a read/write circuit or a computing circuit, is electrically coupled to the array of memory cells formed in the BEOL network. In this way, the array of the memory cells in the BEOL network and the peripheral circuit in the FEOL network are stacked and integrated with each other in a three-dimensional (3D) way, thereby being space efficient.

In some embodiments, each of the array of memory cells in the BEOL network includes an access transistor and a storage capacitor (in a “1T1C” configuration) that are electrically coupled to each other in series and are physically arranged with respect to each other along a vertical direction. In some embodiments, the access transistor includes a channel extending along the vertical direction and including a semiconductive-behaving material, thereby forming a vertical selection transistor. In some embodiments, the storage capacitor includes a first metal layer, a capacitor dielectric layer, and a second metal layer. Each of the first metal layer, the capacitor dielectric layer, and the second metal layer of the storage capacitor has at least a portion extending along the vertical direction. In some embodiments, the first metal layer of the storage capacitor is disposed directly above the channel of the access transistor along the vertical direction, with the capacitor dielectric layer surrounding the first metal layer and the second metal layer further surrounding the capacitor dielectric layer.

In some embodiments, the semiconductive-behaving material of the channel of the access transistor, with n-type conductivity, includes at least one of indium gallium zinc oxide (IGZO), zinc oxide (ZnO), indium oxide (In₂O₃), or tin oxide (SnO₂). In other embodiments, the semiconductive-behaving material of the channel of the access transistor, with p-type conductivity, includes at least one of nickel oxide (NiO), cuprous oxide (Cu₂O), copper aluminum oxide (CuAlO₂), copper gallium oxide (CuGaO₂), copper oxide/indium oxide granules (CuInO₂), strontium copper oxide (SrCu₂O₂), or stannous oxide (SnO).

In some embodiments, a first one of the plurality of metal tracks in the BEOL network, operatively serving as a bit line (BL) of the plurality of memory cells, extends along a first lateral direction; and multiple second ones of the plurality of metal tracks in the BEOL network, operatively serving as respective word lines (WLs) of the plurality of memory cells, extend along a second lateral direction perpendicular to the first lateral direction, and are disposed above the bit line. In some embodiments, the WLs are positioned on top of the BL in the BEOL network, and electrically connected to one or more of the peripheral circuits in the FEOL network through metal lines and/or metal vias that are laterally positioned beyond a memory array region of the array of the memory cells. As such, routings of the BL and the WLs of the memory device are shortened, thereby speed and performance of the memory device being improve.

Various advantages may be presented by the semiconductor memory device having such a memory structure and placed in the BEOL network. For example, the semiconductor memory device and the method of fabricating the same can result in improved integration of computing and memory (CIM), reduced cost and area, lowered leakage, increased speed, thereby leading to improved performance thereof.

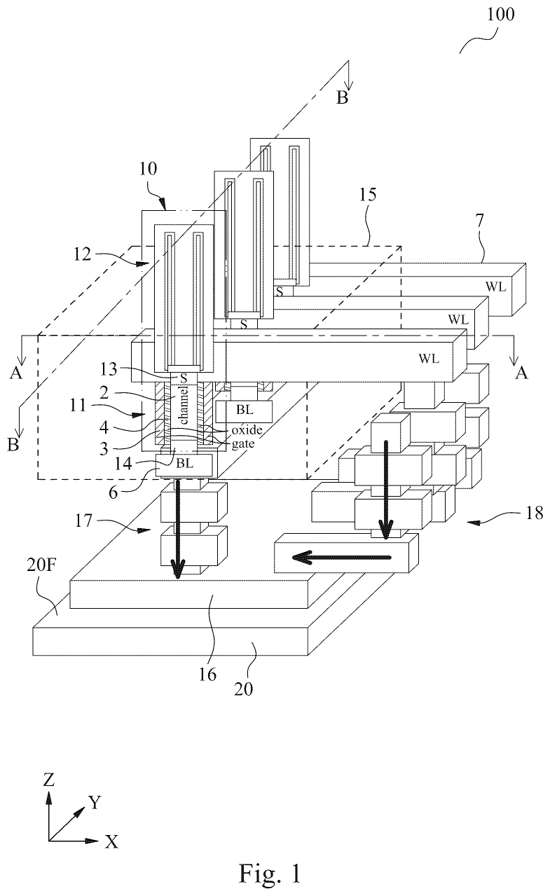

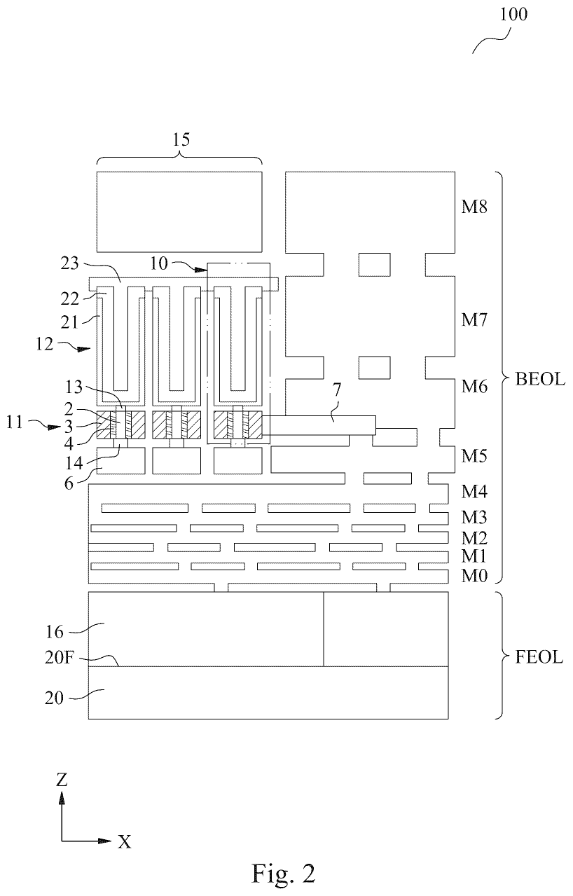

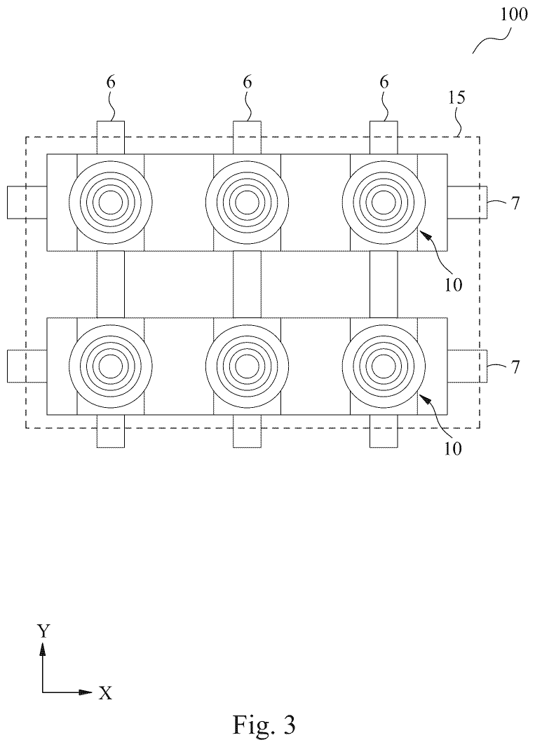

FIG. 1 is a perspective view illustrating a semiconductor memory device 100 in accordance with some embodiments of the present disclosure. FIG. 2 is a schematic cross-sectional view illustrating the semiconductor memory device 100 taken along line A-A of FIG. 1. FIG. 3 is a top view illustrating the semiconductor memory device 100 as shown in FIG. 1 in accordance with some embodiments. The semiconductor memory device 100 includes a three-dimensional (3D) memory structure in a space defined by X-, Y- and Z-axes that are substantially perpendicular to each other. The memory structure includes at least one memory cell 10. Three memory cells 10 are exemplarily depicted in FIG. 1, but the number of the memory cells 10 is not limited to the disclosure herein. Each of the memory cells 10 includes an access transistor 11 and a storage capacitor 12 that are electrically connected to the access transistor 11 in series, and thus is a 1T1C structured memory cell. In some embodiments, the semiconductor memory device 100 is fabricated in the BEOL process. In some embodiments, the memory structure of the semiconductor memory device 100 may be, for example, DRAM. However, other suitable memory structures (such as RAM, and NAND) are also within the contemplated scope of the disclosure.

In accordance with some embodiments, the semiconductor memory device 100 may be formed in an interlayer dielectric (ILD) layer of the BEOL. The ILD layer may include a dielectric material such as, but not limited to, oxide, silicon oxide, a low-k material, or combinations thereof. For example, the ILD layer may include, but not limited to, silica (Si02), hafnium silicate (HfSi04), zirconium silicate (ZrSi04), or combinations thereof. In alternative embodiments, the ILD layer may include, but not limited to, polyimide, epoxy resin, acrylic resin, phenol resin, benzocyclobutene (BCB), polybenzooxazole (PBO), other suitable polymer-based dielectric materials, or combinations thereof. Other suitable dielectric materials are within the contemplated scope of the present disclosure.

In accordance with some embodiments, as shown in FIGS. 1 and 2, a plurality of transistors 16 (e.g., peripheral transistors) are disposed along a major surface (e.g., a front surface) 20F of a substrate 20, and a plurality of metallization layers (such as M0, M1, M2, M3, M4, M5, M6, M7, M8, etc.) are disposed over the major surface 20F of the substrate 20. The metallization layers include a plurality of metal tracks (such as a metal track 7) and metal vias. In some embodiments, a plurality of memory cells 10 are formed within one or more of the metallization layers (such as M5, M6, M7) and positioned within a memory array region 15. In some embodiments, one or more of the transistors 16 (such as a power circuit, a read and write circuit, and an input/output (I/O) circuit) are electrically coupled to the plurality of memory cells 10 through a plurality of first conductive connectors 17 (including a plurality of metal lines and vias) and/or a plurality of second conductive connectors 18 (including a plurality of metal lines and vias). In some embodiments, each of the plurality of memory cells 10 includes an access transistor 11 and a storage capacitor 12 (in a 1T1C structure) that are electrically coupled to each other in series and physically arranged with respect to each other along a vertical direction (Z direction). For example, at least one of the plurality of transistors 16 may apply a voltage to a storage capacitor 12 of a memory cell 10 of the semiconductor memory device 100 through a second conductive connector 18.

In accordance with some embodiments, the access transistor 11 of the memory cell 10 includes a channel 2 extending along the vertical direction and including a semiconductive-behaving material, a gate electrode (or terminal) 3 wrapping around a sidewall of the channel 2, and a gate dielectric 4 disposed between the vertical channel 2 and the gate electrode 3. In some embodiments, the semiconductive-behaving material has n-type conductivity, while in other embodiments, the semiconductive-behaving material has p-type conductivity. In some embodiments, the semiconductive-behaving material, with n-type conductivity, includes at least one of indium gallium zinc oxide (IGZO), zinc oxide (ZnO), indium oxide (In₂O₃), or tin oxide (SnO₂). In other embodiments, the semiconductive-behaving material, with p-type conductivity, includes at least one of nickel oxide (NiO), cuprous oxide (Cu₂O), copper aluminum oxide (CuAlO₂), copper gallium oxide (CuGaO₂), copper oxide/indium oxide granules (CuInO₂), strontium copper oxide (SrCu₂O₂), or stannous oxide (SnO).

In accordance with some embodiments, as shown in FIGS. 1 and 2, the access transistor 11 of the memory cell 10 includes a source contact 13 (such as a metal track) that is positioned directly above the vertical channel 2 along the vertical direction (Z direction) and electrically connects a source of the access transistor 11 to the storage capacitor 12. In some embodiments, the access transistor 11 of the memory cell 10 also includes a drain contact 14 that is positioned directly under the channel 2 and electrically connects a drain of the access transistor 11 to a bit line (BL) 6, which is positioned directly under the channel 2 and extends along a first horizontal direction (Y direction). The gate electrode 3 of the access transistor 11 is electrically connected to a word line (WL) 7. In some embodiments, one or more WLs 7 are positioned directly above one or more BLs 6 and extend in parallel along a second horizontal direction (X direction) that is perpendicular to the first horizontal direction.

In accordance with some embodiments, as shown in FIGS. 1 and 2, the storage capacitor 12 of the memory cell 10 includes a first metal layer 21, a capacitor dielectric layer 22, and a second metal layer 23, and each of the first metal layer 21, the capacitor dielectric layer 22, and the second metal layer 23 has at least a portion extending along the vertical direction (Z direction). In some embodiments, the first metal layer 21 is disposed directly above the vertical channel 2 along the vertical direction, the first metal layer 21 surrounds the capacitor dielectric layer 22, and the capacitor dielectric layer 22 further surrounds the second metal layer 23. In some embodiments, the source contact 13 that is positioned directly above the vertical channel 2 of the access transistor 11 is directly positioned under the first metal layer 21 of the storage capacitor 12 and is electrically connected to the first metal layer 21.

Referring to FIG. 1, the semiconductor memory device 100 exemplarily includes three memory cells 10 and three WLs 7 over three BLs 6. However, the numbers of the memory cells 10, the WL7, and the BLs 6 of the semiconductor memory device 100 are not limited to the example shown in FIG. 1. As shown in FIGS. 1 and 2, since the storage capacitors 12 are stacked over the access transistors 11, the memory cells 10 of the semiconductor memory device 100 are stacked-capacitor cells, forming a three-dimension (3D) structure or configuration.

Referring to FIG. 2, three memory cells 10 of FIG. 1 are exemplarily illustrated from the perspective of the schematic cross-sectional view of FIG. 1. For example, in each of the three memory cells 10, the access transistor 11 includes a channel layer (or channel) 2 extending along the vertical direction (Z direction), a gate electrode 3 wrapping the channel layer 2, and a gate dielectric 4 positioned between the channel layer 2 and the gate electrode 3, a source contact 13, and a drain contact 14. The source contact 13 is electrically connected to the storage capacitor 12 directly positioned above the vertical channel layer 2, and the drain contact 14 is electrically connected to the bit line 6 directly positioned under the vertical channel layer 2. The gate dielectric 4 is formed on a sidewall of the channel layer 2 and fully surrounding the channel layer 2. The gate electrode 3 is formed on a sidewall of the gate dielectric 4 and fully surrounding the gate dielectric 4. The gate electrode 3 is electrically connected to a WL 7, which is electrically connected to one or more of the transistors 16 (e.g., a read and write circuit) through one or more of a plurality of second connectors 18. The second conductive connectors 18 include a plurality of metal lines and metal vias that are formed laterally outside or beyond the memory array region 15 of the memory device 100, thereby advantageously saving space for the semiconductor memory device 100 and improving integration thereof. The BL 6 is positioned directly under one or more access transistors 11, and is electrically connected to the one or more access transistors 11 through one or more of a plurality of first conductive connectors 17. As such, the routings from the one or more access transistors 11 to the BL 6 are shortened, thereby achieving improved speed.

As shown in FIG. 3, the semiconductor memory device 100 includes a plurality of memory cells 10 that are laterally positioned within a memory array region 15 and are electrically connected to a plurality of BLs 6 and a plurality of WLs 7. The plurality of BLs 6 extend in a first horizontal direction (Y direction), and the plurality of WLs 7 extend in a second horizontal direction (X direction) that is perpendicular to the first horizontal direction. In some embodiments, the semiconductor memory device 100 is formed within one or more of the plurality of metallization layers (such as M5, M6, M7) in a BEOL network as shown in FIG. 2.

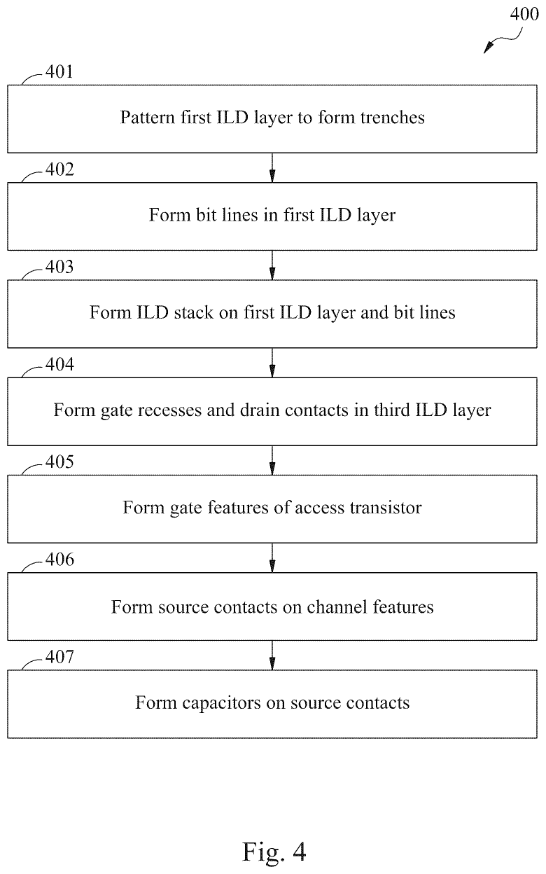

FIG. 4 is a flow diagram illustrating a method 400 for manufacturing a semiconductor memory device 100 as shown in FIGS. 1 and 2 in accordance with some embodiments of the present disclosure. It should be noted that the method 400 as shown in FIG. 4 is merely an example, and is not intended to limit the present disclosure. Accordingly, it is understood that the order of the operations of the method 400 as shown in FIG. 4 can be changed, for example, additional operations may be provided before, during, and after the method 400 of FIG. 4, and that some operations may only be described briefly herein.

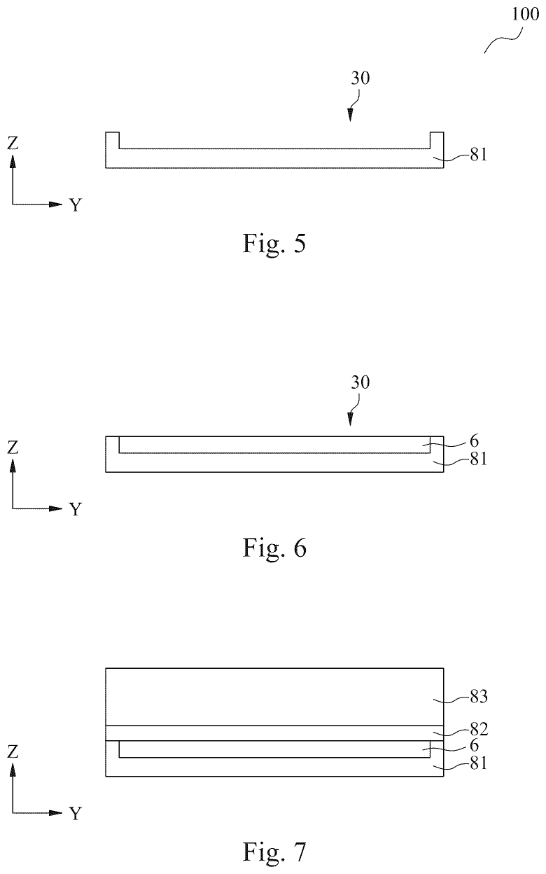

FIGS. 5, 6, 7, 8, 9, 10 and 11 are schematic cross-sectional views illustrating the semiconductor memory device 100 as shown in FIG. 1 taken along line B-B, at intermediate stages of the method as depicted in FIG. 4, in accordance with some embodiments.

Referring to FIG. 4, the method 400 begins at operation 401, where a first ILD layer 81 is patterned to form trenches. Referring to the example illustrated in FIG. 5, the first ILD layer 81 is patterned by using a photolithography process and an etching process so as to form a trench (e.g., a bit line trench) 30 in the first ILD layer 81. In some embodiments, the first ILD layer may be a single material layer. In alternative embodiments, the first ILD layer 81 may include multiple films made of different materials. The first ILD layer may be formed by using, for example, but not limited to, chemical vapor deposition (CVD), physical vapor deposition (PVD), sputtering, combinations thereof, or other suitable techniques. In some embodiments, the material for making the first ILD layer 81 is similar to those for making the ILD layer of the BEOL described above, and the details thereof are omitted herein for the sake of brevity.

The photolithography process may include, for example, but not limited to, coating a photoresist, soft baking, exposing the photoresist through a photomask, postexposure baking, and developing the photoresist, followed by hard-baking, so as to form a patterned photoresist. The etching process for patterning the first ILD layer may be implemented by etching the first ILD layer through the patterned photoresist using, for example, but not limited to, a dry etching process, a wet etching process, other suitable processes, or combinations thereof. In some embodiments, operation 401 may be implemented in the BEOL of the fabrication process.

Referring to FIG. 4, the method 400 then proceeds to operation 402, where bit lines 6 are formed in the first ILD layer 81. Referring to the example illustrated in FIG. 6, a bit line 6 is formed in the trench 30 of the first ILD layer 81 by depositing a conductive material to fill the trench 30 and then removing excess of the conductive material above the first ILD layer 81 by a planarization technique, such as chemical mechanical planarization (CMP). In some embodiments, the conductive material may include metallic material, for example, but not limited to, ruthenium (Ru), cobalt (Co), molybdenum (Mo), tungsten (W), nickel (Ni), iridium (Ir), rhodium (Rh), osmium (Os), or the like, metal nitride, for example, but not limited to, titanium nitride (TiN), tantalum nitride (TaN), or the like, or combinations thereof. In some embodiments, deposition of the metal material may be conducted by a suitable fabrication technique known to those skilled in the art of semiconductor fabrication, for example, but not limited to, CVD, plasma-enhanced CVD (PECVD), atomic layer deposition (ALD), plasma-enhanced ALD (PEALD), or other suitable deposition techniques.

Referring to FIG. 4, the method 400 then proceeds to operation 403, where an ILD stack is formed on the first ILD layer 81 and the bit lines 6. Referring to the example illustrated in FIG. 7, a second ILD layer 82 is formed on the first ILD layer 81 and the bit line 6, an etch stop layer (not shown) is then formed on the second ILD layer 82, and a third ILD layer 83 is later formed on the etch stop layer. The second ILD layer, the etch stop layer and the third ILD layer constitute the ILD stack. The materials and processes used for forming the second ILD layer and the third ILD layer are similar to those for forming the first ILD layer, and the details thereof are omitted herein for the sake of brevity. It is noted that each of the second ILD layer and the third ILD layer may include a material that is different from that of the first ILD layer, or a material that is exactly the same as that of the first ILD layer. Similarly, the second ILD layer may include a material that is different from that of the third ILD layer, or a material that is exactly the same as that of the third ILD layer. The etch stop layer is formed on the second ILD layer by a suitable fabrication technique known to those skilled in the art of semiconductor fabrication, for example, but not limited to, CVD, ALD, PVD, PECVD, or the like. In some embodiments, the etch stop layer may be made of a dielectric material, for example, but not limited to, silicon nitride, silicon nitride doped with carbon, silicon oxide, silicon oxynitride, silicon oxynitride doped with carbon, amorphous carbon material, silicon carbide, other nitride materials, other carbide materials, aluminum oxide, other oxide materials, other metal oxides, boron nitride, boron carbide, other low-k dielectric materials, other low-k dielectric materials doped with one or more of carbon, nitrogen and hydrogen, or other suitable materials.

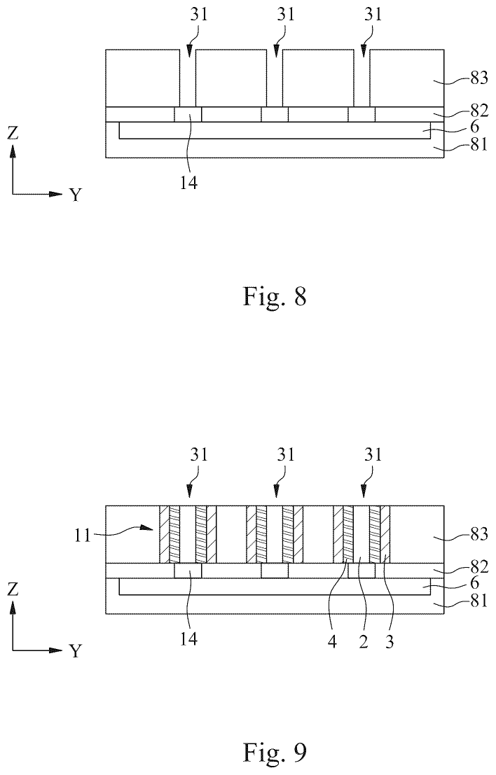

Referring to FIG. 4, the method 400 then proceeds to operation 404, where a plurality of gate recesses 31 are formed in the third ILD layer 83, and a plurality of conductive connectors such as drain contacts 14 (also in FIGS. 1 and 2) are formed in the plurality of gate recesses 31. Referring to the example illustrated in FIG. 8, the third ILD layer 83 is recessed by an anisotropic etching process, through a patterned photoresist, to form a plurality of gate recesses 31 in the third ILD layer 83. The anisotropic etching process may be a suitable anisotropic etching process, for example, but not limited to, anisotropic dry etching. Because of the existence of the etch stop layer, etching of the third ILD layer would stop at the etch stop layer, and the recesses would not be formed in the second ILD layer.

Referring to FIG. 4, the method 400 then proceeds to operation 405, where a plurality of gate features (such as a gate electrode 3 and a gate dielectric 4) of an access transistor 11 are formed. Referring to the example illustrated in FIG. 9, a semiconductive-behaving material is filled in the gate recesses 31 that are formed in the third ILD layer 83, and then a planarization process (for example, but not limited to, CMP) is conducted to remove excess of the semiconductive-behaving material above the third ILD layer 83, and then a plurality of gate features are formed in the third ILD layer 83. FIG. 9 is a cross-sectional view of the semiconductor memory device 100 to show an intermediate stage of forming gate features of the access transistor 11, such as a channel layer 2, a gate electrode 3 wrapping the channel layer 2, and a gate dielectric 4 positioned between the channel layer 2 and the gate electrode 3 (also shown in FIGS. 1 and 2). The vertical channel layer 2 of the access transistor 11 is electrically connected to a BL 6 through the drain contact 14 that is disposed directly under the vertical channel layer 2. Filling of the semiconductive-behaving material in the recesses may be implemented through a blanket deposition process using CVD, PECVD, sub-atmospheric CVD (SACVD), molecular layer deposition (MLD), PVD, ALD, sputtering, other suitable methods, or combinations thereof. Various semiconductor processes such as lithography, etching, deposition, CMPs, etc. can be used in fabricating gate features of the access transistor. The semiconductive-behaving material is similar to those described above, and details thereof are omitted herein for the sake of brevity.

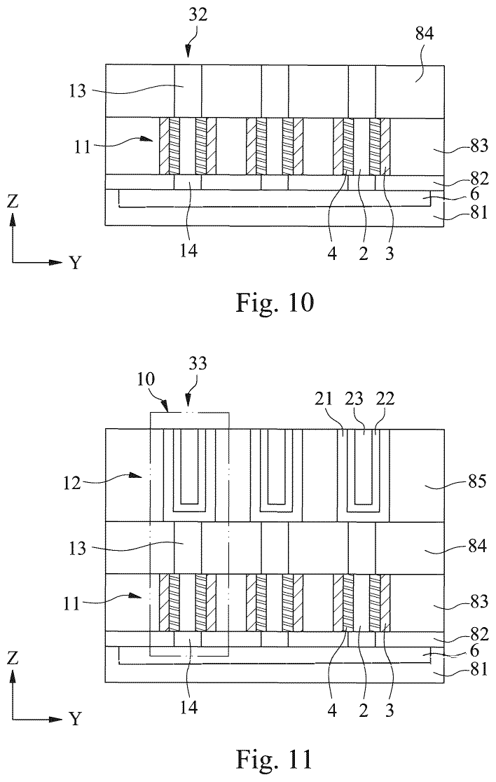

Referring to FIG. 4, the method 400 then proceeds to operation 406, where a fourth ILD layer 84 is formed, a plurality of connector recesses 32 are formed in the fourth ILD layer 84, and then a plurality of conductive connectors 13 (such as source contacts 13 also shown in FIGS. 1 and 2) are formed in the plurality of connector recesses 32. Referring to the example illustrated in FIG. 10, the fourth ILD layer 84 is recessed by an anisotropic etching process, through a patterned photoresist, to form a plurality of connector recesses 32 in the fourth ILD layer 84. The anisotropic etching process may be a suitable anisotropic etching process, for example, but not limited to, anisotropic dry etching. Because of the existence of the etch stop layer, etching of the fourth ILD layer 84 would stop at the etch stop layer, and the recesses 32 would not be formed in the third ILD layer 83.

Referring to FIG. 4, the method 400 then proceeds to operation 407, where a fifth ILD layer 85 is formed on top of the fourth ILD layer 84, a plurality of capacitor recesses 33 are formed in the fifth ILD layer 85, and then a plurality of storage capacitors 12 are formed in the plurality of capacitor recesses 33. In some embodiments, as shown in FIG. 11, the storage capacitor 12 includes a first metal layer 21, a capacitor dielectric layer 22, and a second metal layer 23, and each of the first metal layer 21, the capacitor dielectric layer 22, and the second metal layer 23 has at least a portion extending along the vertical direction (Z direction). In some embodiments, the first metal layer 21 is disposed directly above the vertical channel 2 along the vertical direction, the first metal layer 21 surrounds the capacitor dielectric layer 22, and the capacitor dielectric layer 22 further surrounds the second metal layer 23. In some embodiments, the source contact 13 that is positioned directly above the vertical channel 2 of the access transistor 11 along the vertical direction is directly positioned under the first metal layer 21 of the storage capacitor 12 along the vertical direction and is electrically connected to the first metal layer 21. The material and process used for forming the fifth ILD layer 85 are similar to those for forming the first ILD layer, and the details thereof are omitted herein for the sake of brevity. Various semiconductor processes such as lithography, etching, deposition, CMPs, etc. can be used in fabricating the features of the plurality of storage capacitors 12, and thus details thereof are omitted herein for the sake of brevity.

As shown in FIG. 11, in accordance with some embodiments of the present disclosure, a semiconductor memory device 100 includes a bit line (BL) 6, and a plurality of memory cells 10. Each of the plurality of memory cells 10 includes an access transistor 11 positioned directly above the bit line 6 along a vertical direction (Z direction), a storage capacitor 12 positioned directly above the access transistor 11 along the vertical direction and electrically connected with the access transistor 11 in series, a source contact 13 electrically connecting the access transistor 11 to the storage capacitor 12, and a drain contact 14 electrically connecting the access transistor 11 to the bit line (BL) 6. In some embodiments, as shown in FIG. 2, an array of memory cells 10 of the semiconductor memory device 100 are formed in a BEOL network, for example, in upper metallization layers (such as M5, M6, M7 . . . ). Upper metallization layers in the semiconductor memory device 100 are thicker than lower metallization layers (such as M0), and metal lines and vias in upper metallization layers are wider than those in lower metallization layers. As such, the semiconductor memory device 100, with the memory cells 10 formed in upper metallization layers of the BEOL network, can achieve reduced metal resistance and thus power IR drop, thereby resulting in improved performance thereof.

As shown in FIG. 11, in some embodiments, the access transistor 11 includes a vertical channel layer 2 upwardly extending from the bit line 6 in the vertical direction, a gate electrode 3 laterally surrounding the vertical channel layer 2, and a gate dielectric 4 disposed between the vertical channel layer 2 and the gate electrode 3. In some embodiments, the storage capacitor 12 includes a first metal layer 21, a capacitor dielectric layer 22, and a second metal layer 23, and each of the first metal layer 21, the capacitor dielectric layer 22, and the second metal layer 23 has at least a portion extending along the vertical direction. In some embodiments, the first metal layer 21 is disposed directly above the vertical channel 2 along the vertical direction, the first metal layer 21 surrounds the capacitor dielectric layer 22, and the capacitor dielectric layer 22 further surrounds the second metal layer 23.

As shown in FIG. 11, in some embodiments, the source contact 13 is positioned directly above the vertical channel 2 of the access transistor 11 along the vertical direction and is directly positioned under the first metal layer 21 of the storage capacitor 12 along the vertical direction, thereby electrically connecting the first metal layer 21 of the storage capacitor 12 to the access transistor 11. In some embodiments, the drain contact 14 is positioned directly under the vertical channel 2 of the access transistor 11 along the vertical direction, and is electrically connected to the bit line 6 that is directly positioned under the vertical channel layer 2. As such, a routing from the vertical channel 2 of the access transistor 11 to the BL 6 is shortened, thereby advantageously increasing speed of the semiconductor memory device 100 and improving performance thereof.

As shown in FIGS. 2 and 11, in some embodiments, the gate electrode 3 is electrically connected to a WL 7, and thus is a portion of the WL7, which is electrically coupled to one or more of the transistors (or peripheral transistors) 16 (e.g., a read circuit and a write circuit) through one or more of the plurality of second conductive connectors 18. As shown in FIG. 2, in some embodiments, the semiconductor memory device 100 is formed within one or more of the plurality of metallization layers (such as M5, M6, M7) in a BEOL network. For example, referring to FIG. 3, the semiconductor memory device 100 includes a plurality (e.g., three) of memory cells 10 that are laterally positioned in a memory array region 15 and are electrically connected to a plurality (e.g., three) of BLs 6 and a plurality (e.g., three) of WLs 7, in which the BLs 6 extend in a first horizontal direction (Y direction), and the WLs 7 extend in a second horizontal direction (X direction) perpendicular to the first horizontal direction. Since the second conductive connectors 18 including a plurality of metal lines and metal vias are positioned laterally outside or beyond the memory array region 15 of the semiconductor memory device 100, the area of the semiconductor memory device is more efficient.

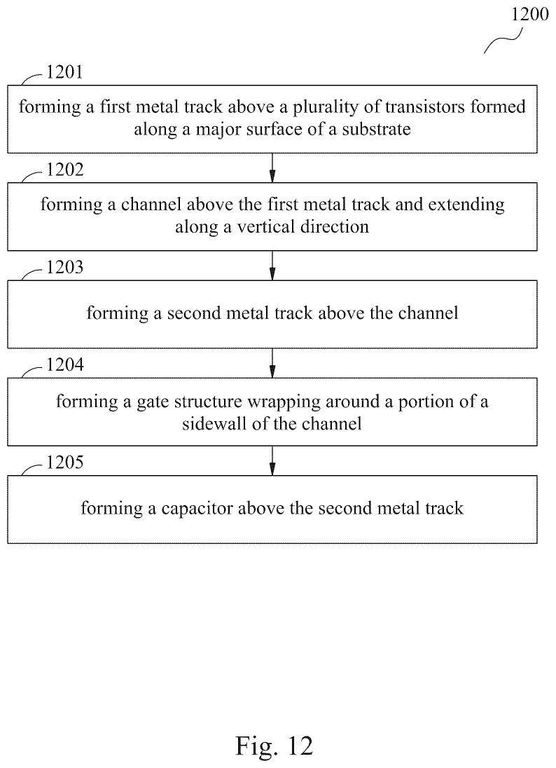

FIG. 12 is another flow diagram illustrating a method for manufacturing a semiconductor memory device 100 as shown in FIGS. 1, 2, 3 and 11 in accordance with some embodiments. It should be noted that the method 1200 as shown in FIG. 12 is merely an example, and is not intended to limit the present disclosure. Accordingly, it is understood that the order of the operations of the method 1200 as shown in FIG. 12 can be changed, for example, additional operations may be provided before, during, and after the method 1200 of FIG. 12, and that some operations may only be described briefly herein.

In some embodiments, a semiconductor memory device 100 as shown in FIGS. 1, 2, 3 and 11 includes a bit line (BL) 6, and an array of memory cells 10. Each of the array of memory cells 10 includes an access transistor 11 positioned directly above the bit line 6 along a vertical direction (Z direction), a storage capacitor 12 positioned directly above the access transistor 11 along the vertical direction and electrically connected with the access transistor 11 in series, a source contact 13 for electrically connecting the access transistor 11 to the storage capacitor 12, and a drain contact 14 for electrically connecting the access transistor 11 to the bit line 6. In some embodiments, the memory cells 10 of the semiconductor memory device 100 are formed in a BEOL network as shown in FIG. 2, for example, in upper metallization layers (such as M5, M6, M7 . . . ).

Referring to FIG. 12, the method 1200 begins at operation 1201 of forming a first metal track above a plurality of transistors formed along a major surface of a substrate, in which the first metal track extends along a first lateral direction. Referring to the example illustrated in FIGS. 1 and 2, a plurality of transistors 16 (e.g., serving as peripheral transistors) are formed along a major surface (e.g., a front surface) 20F of a substrate 20, and a plurality of metallization layers (such as M0, M1, M2, M3, M4, M5, M6, M7, M8, etc.) are formed over the major surface 20F of the substrate 20. The plurality of metallization layers include a plurality of metal tracks. For example, a first metal track 6 is formed in a metallization layer (e.g., M5) of the plurality of metallization layers in a BEOL process, and will serve as a bit line (BL) 6 in the semiconductor memory device 100. Various semiconductor processes such as lithography, etching, deposition, CMPs, etc. can be used in fabricating the first metal track, and thus details thereof are omitted herein for the sake of brevity.

Referring to FIG. 12, the method 1200 proceeds to operation 1202 of forming a channel that is positioned above the first metal track and extends along a vertical direction. Referring to the example illustrated in FIGS. 1 and 2, a vertical channel layer 2 is formed, which upwardly extends from the bit line 6 in a vertical direction (Z direction). The channel layer 2 includes a semiconductive-behaving material that has n-type or p-type conductivity. In some embodiments, the semiconductive-behaving material of the channel layer of the access transistor, with n-type conductivity, includes at least one of: indium gallium zinc oxide (IGZO), zinc oxide (ZnO), indium oxide (In₂O₃), or tin oxide (SnO₂). In other embodiments, the semiconductive-behaving material of the channel layer of the access transistor, with p-type conductivity, includes at least one of: nickel oxide (NiO), cuprous oxide (Cu₂O), copper aluminum oxide (CuAlO₂), copper gallium oxide (CuGaO₂), copper oxide/indium oxide granules (CuInO₂), strontium copper oxide (SrCu₂O₂), or stannous oxide (SnO).

Referring to FIG. 12, the method 1200 proceeds to operation 1203 of forming a second metal track above the vertical channel along the vertical direction. Referring to the example illustrated in FIGS. 1 and 2, a second metal track 13 (which will serve as a source contact 13) is formed above the vertical channel 2 along the vertical direction. Various semiconductor processes such as lithography, etching, deposition, CMPs, etc. can be used in fabricating the second metal track, and thus details thereof are omitted herein for the sake of brevity.

Referring to FIG. 12, the method 1200 proceeds to operation 1204 of forming a gate structure wrapping around a portion of a sidewall of the channel. Referring to the example illustrated in FIGS. 1 and 2, a gate structure is formed, which wraps around a portion of a sidewall of the vertical channel layer 2. For example, the vertical channel layer 2 upwardly extends from the bit line 6 in the vertical direction, a gate electrode 3 laterally surrounds the vertical channel layer 2, and a gate dielectric 4 is disposed between the vertical channel layer 2 and the gate electrode 3, thereby forming an access transistor 11. Various semiconductor processes such as lithography, etching, deposition, oxidation, CMPs, etc. can be used in fabricating the access transistor, and thus details thereof are omitted herein for the sake of brevity.

Referring to FIG. 12, the method 1200 proceeds to operation 1205 of forming a storage capacitor above the second metal track. Referring to the example illustrated in FIGS. 1 and 2, a storage capacitor 12 is formed above the second metal track 13, which will serve as a source contact 13 in the finished product. In some embodiments, the storage capacitor 12 includes a first metal layer 21, a capacitor dielectric layer 22, and a second metal layer 23, and each of the first metal layer 21, the capacitor dielectric layer 22, and the second metal layer 23 has at least a portion extending along the vertical direction. In some embodiments, at least one portion of the first metal layer 21 is disposed directly above the vertical channel 2 along the vertical direction, the first metal layer 21 surrounds the capacitor dielectric layer 22, and the capacitor dielectric layer 22 further surrounds the second metal layer 23. The source contact 13 is electrically connected to the first metal layer 21 of the storage capacitor 12. Various semiconductor processes such as lithography, etching, deposition, oxidation, CMPs, etc. can be used in fabricating the storage capacitor, and thus details thereof are omitted herein for the sake of brevity.

In one aspect of the present disclosure, a semiconductor device is disclosed. The semiconductor device includes a first metal track disposed above a substrate; a first channel disposed above and coupled to the first metal track, the first channel including a semiconductive-behaving material and extending along a vertical direction; a first gate structure wrapping around a sidewall of the first channel; a second metal track disposed above and coupled to the first channel; and a first capacitor disposed above and coupled to the second metal track, the first capacitor including a first metal layer, a first capacitor dielectric layer, and a second metal layer. Each of the first metal layer, the first capacitor dielectric layer, and the second metal layer has at least a portion extending along the vertical direction.

In another aspect of the present disclosure, a semiconductor device is disclosed. The semiconductor device includes a plurality of transistors disposed along a major surface of a substrate; and a plurality of metallization layers disposed over the major surface of the substrate, the metallization layers including a plurality of metal tracks. The plurality of memory cells are formed within one or more of the metallization layers, at least one of the transistors electrically coupled to the plurality of memory cells. Each of the plurality of memory cells includes an access transistor and a storage capacitor that are electrically coupled to each other in series and are physically arranged with respect to each other along a vertical direction.

In yet another aspect of the present disclosure, a method for fabricating semiconductor devices is disclosed. The method includes forming a first metal track above a plurality of transistors formed along a major surface of a substrate, wherein the first metal track extends along a first lateral direction; forming a channel above the first metal track, wherein the channel extends along a vertical direction; forming a second metal track above the channel; forming a gate structure wrapping around a portion of a sidewall of the channel; and forming a capacitor above the second metal track. The capacitor includes a first metal layer, a capacitor dielectric layer surrounding the first metal layer, and a second metal layer further surrounding the capacitor dielectric layer. Each of the first metal layer, the capacitor dielectric layer, and the second metal layer has at least one portion extending along the vertical direction. The at least one portion of the first metal layer is disposed directly above the channel.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or +35% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of memory cells formed along a back surface of a substrate, each memory cell comprising:
a transistor;
a word line disposed above the transistor and operatively coupled to the transistor;
a bit line disposed below the transistor and operatively coupled to the transistor
a first capacitor disposed above the transistor and operatively coupled to the transistor in series; and
a second capacitor disposed above the first capacitor and operatively coupled to the first capacitor in series,
wherein the transistor, the first capacitor, and the second capacitor extend long a vertical direction, the word line extends along a first horizontal direction perpendicular to the vertical direction, and the bit line extends along a second horizontal direction perpendicular to the vertical direction and the first horizontal direction.

2. The memory device of claim 1, wherein the transistor comprises:
a channel layer extending along the vertical direction;
a gate electrode surrounding the channel layer and operatively coupled to the word line; and
a gate dielectric disposed between the channel layer and the gate electrode.

3. The memory device of claim 1, where the transistor is a first transistor, further comprising:
a plurality of second transistors formed along a front surface of the substrate and operatively coupled to one or more corresponding memory cells.

4. The memory device of claim 3, wherein at least one of the plurality of second transistors operates as at least one of a read/write circuit, a power circuit, or an input/output circuit.

5. The memory device of claim 3, wherein some of the plurality of second transistors are operatively coupled to corresponding bit lines via a plurality of first connectors and some of the plurality of second transistors are operatively coupled to corresponding word lines via a plurality of second connectors.

6. The memory device of claim 1, wherein a source contact of the transistor is operatively coupled to the first capacitor and a drain contact of the transistor is operatively coupled to the bit line.

7. The memory device of claim 1, wherein the plurality of memory cells are formed within a plurality of metallization layers disposed atop the substrate and extending along the vertical direction.

8. The memory device of claim 6, wherein a corresponding width of each metallization layer increases as a distance between each metallization layer and the substrate increases.

9. The memory device of claim 1, wherein the plurality of memory cells are formed along a plurality of interlayer dielectric layers of the substrate.

10. The memory device of claim 9, wherein some of the plurality of interlayer dielectric layers of the substrate include trenches configured to receive conductive material.

11. A memory device, comprising:
a memory cell formed along a back surface of a substrate, the memory cell comprising:
a transistor;
a word line disposed above the transistor and operatively coupled to the transistor;
a bit line disposed below the transistor and operatively coupled to the transistor
a first capacitor disposed above the transistor and operatively coupled to the transistor; and
a second capacitor disposed above the first capacitor and operatively coupled to
the first capacitor,
wherein the transistor, the first capacitor, and the second capacitor extend long a vertical direction, the word line extends along a first horizontal direction perpendicular to the vertical direction, and the bit line extends along a second horizontal direction perpendicular to the vertical direction and the first horizontal direction.

12. The memory device of claim 11, wherein the transistor comprises:
a channel layer extending along the vertical direction;
a gate electrode surrounding the channel layer and operatively coupled to the word line; and
a gate dielectric disposed between the channel layer and the gate electrode.

13. The memory device of claim 11, where the transistor is a first transistor, further comprising:
a plurality of second transistors formed along a front surface of the substrate and operatively coupled to the memory cell.

14. The memory device of claim 13, wherein at least one of the plurality of second transistors operates as at least one of a read/write circuit, a power circuit, or an input/output circuit.

15. The memory device of claim 13, wherein some of the plurality of second transistors are operatively coupled to corresponding bit lines via a plurality of first connectors and some of the plurality of second transistors are operatively coupled to corresponding word lines via a plurality of second connectors.

16. The memory device of claim 11, wherein a source contact of the transistor is operatively coupled to the first capacitor and a drain contact of the transistor is operatively coupled to the bit line.

17. The memory device of claim 11, wherein the memory cell is formed within a plurality of metallization layers disposed atop the substrate and extending along the vertical direction.

18. The memory device of claim 16, wherein a corresponding width of each metallization layer increases as a distance between each metallization layer and the substrate increases.

19. The memory device of claim 11, wherein the memory cell is formed along a plurality of interlayer dielectric layers of the substrate.

20. A memory device, comprising:
plurality of a memory cells formed along a back surface of a substrate, each memory cell comprising:
a transistor including a source contact, a drain contact, and a gate electrode;
a word line disposed above the transistor and operatively coupled to the gate electrode of the transistor;
a bit line disposed below the transistor and operatively coupled to the drain contact of the transistor;
a first capacitor disposed above the transistor and operatively coupled to the source contact of the transistor; and
a second capacitor disposed above the first capacitor and operatively coupled to the first capacitor.
